(19) United States
(12) Patent Application Publication
(10) Pub. No.: US 2010/0068889 A1
(43) Pub. Date: Mar. 18, 2010

(54) PARTICLE-CONTAINING ETCHING PASTES FOR SILICON SURFACES AND LAYERS

(75) Inventors: Werner Stockum, Reinheim (DE); Sylke Klein, Rossdorf (DE); Armin Kuebelbeck, Bensheim (DE)

Correspondence Address: MILLEN, WHITE, ZELANO & BRANIGAN, P.C., 2200 CLARENDON BLVD., SUITE 1400, ARLINGTON, VA, 22201, US

(73) Assignee: MERCK PATENT GMBH, Darmstadt (DE)

(21) Appl. No.: 12/447,921

(22) PCT Filed: Oct. 5, 2007
(86) PCT No.: PCT/EP07/08662

§ 371 Date: Apr. 30, 2009

(30) Foreign Application Priority Data
Nov. 1, 2006 (DE) 10 2006 051 952.3

(51) Int. Cl. H01L 21/306; C09K 13/02

(52) U.S. Cl. 438/745; 252/79.1; 252/79.5; 257/E21.219

(57) ABSTRACT

The present invention relates to particle-containing etching media in the form of etching pastes which are suitable for the full-area or selective etching of extremely fine lines or structures in silicon surfaces and layers and in glass-like surfaces formed from suitable silicon compounds. The present invention also relates to the use of the pastes according to the invention in processes for etching surfaces of this type.

The present invention relates to particle-containing etching media in the form of etching pastes which are suitable for full-area or selective etching of extremely fine lines or structures in silicon surfaces and layers and in glass-like surfaces formed from suitable silicon compounds. The present invention also relates to the use of the pastes according to the invention in processes for the etching of such surfaces.

### PRIOR ART

In the photovoltaics, electronics and semiconductor industries, silicon surfaces and layers are often etched by wet-chemical methods in dip baths. This full-area etching can be carried out either in an acidic medium (isotropic etching) or in an alkaline medium (anisotropic etching). In acidic etching, use is frequently made of mixtures of hydrofluoric acid and nitric acid, while in alkaline etching, strong bases, such as sodium hydroxide solution, potassium hydroxide solution, tetramethylammonium hydroxide (TMAH), etc., are frequently used.

In order to produce defined, fine etching patterns or structures (for example for buried structures) in addition to full-area etching (for example polish etches, texture etches), material-intensive, time-consuming and expensive process steps, such as, for example, the photolithographic masking process known to the person skilled in the art, were necessary before the actual etching step up until some time ago.

In a masking process of this type, the starting material is usually a silicon wafer. A dense oxide layer is produced thereon by thermal oxidation and structured as follows.

By coating with a photoresist, subsequent drying, exposure to UV light using a photomask, and subsequent development, the oxide is uncovered at the desired points and then removed using hydrofluoric acid. The photoresist which still remains is subsequently removed (“stripped”), for example using a solvent. The Si wafer thus provided with an oxide mask can then be etched selectively at the points not covered by the oxide in a strong base, such as, for example, 30% KOH. The oxide mask is resistant to the base. After selective etching of the silicon, the oxide mask is usually removed again using hydrofluoric acid.

Lithographic processes of this type are not used in the industrial production of solar cells for cost reasons [1]. However, selective structuring or opening of the silicon surface or layer is also necessary in the modified production process.

During the production of a standard silicon solar cell, the p-n junction necessary for the photoelectric effect is formed on a p-doped wafer, for example by gas diffusion in a POCl₃ oven. An n-doped silicon layer with a thickness of about 500 nm is formed around the entire wafer and has to be partially opened or parted for the later photovoltaic application.

This opening can be carried out mechanically by laser cutting or in a dry-etching process, such as plasma etching.

Disadvantages of mechanical parting, for example grinding-off of the cell edges in the final step of the production process (after metallisation), are associated with losses of silicon material (and metal paste), produce mechanical stress, and may cause crystal defects in the solar cell.

Plasma etching is carried out with fluorinated hydrocarbons, for example with CF₄ or C₂F₆ gas, in expensive vacuum equipment. In this process, the cells are stacked in advance and etched at the cell edges in the plasma-etching unit. Considerable handling problems during stacking and high wafer breakage rates frequently occur in this process. These technological problems will intensify even more in the future since the aim is, owing to high material costs, to use ever thinner polycrystalline silicon starting substrates (<200 μm) compared with the substrate thicknesses of 250-330 μm which are usual today.

Owing to the requisite linear (XY) movement of the punctiform laser source, parting of the p-n junction by laser is a time-consuming, throughput-limiting process. The investment costs for this are considerable. In addition, local crystal defects are generated.

In expensive processes for the production of a selective emitter, which have currently only been developed and used on a laboratory scale, the lithographic oxide masking already described above is used. The oxide masks the wafer in such a way that the areas on which the contacts will later lie remain free. The masked wafer is subjected to phosphorus diffusion and n⁺⁺-doped in the non-masked areas. After removal of the oxide mask, the entire wafer is n⁺-doped [2].

This gives a solar cell with a selective emitter, i.e. with highly doped n⁺⁺ areas with a depth of 2-3 μm (areas without oxide mask and later lying under the contacts) with a doping concentration of about 1*10²⁰ cm⁻³ and a flat (0.5-1 μm) n⁺-doped emitter over the entire solar cell with a doping concentration of about 1*10¹⁹ cm⁻³.

An alternative to the lithography method is the use of screen-printed contact lines as etching mask. For the production thereof, both wet-chemical and plasma-chemical etching are described in the literature. Disadvantages of dipping the screen-printed solar cell into a mixture of HF/HNO₃—besides the intended removal of silicon between the contact lines—are attack of the silicon beneath the contact lines and the etching damage that may arise in the metal contact lines themselves. This causes rapid impairment of the fill factor [3].

Plasma-chemical etching (reactive ion etching, RIE) is carried out using gases, such as, for example, SF₆ or SF₆/O₂, in expensive vacuum equipment and with considerable technological optimisation effort for the process [4], [5], [6].

Besides the formation of the selective emitter, the silicon surface here is structured (roughened, “textured”) on the emitter side in such a way that the antireflection behaviour of the solar cell improves.

WO 2004/032218 A1 discloses a simplified process in which extremely fine lines or structures are produced in the wafer surfaces by the action of selectively printed-on alkaline etching pastes. The pastes used are particle-free compositions in which, for example, KOH or NaOH act as etching components.

A disadvantage of these etching pastes comprising potassium hydroxide or sodium hydroxide is the strong hygroscopicity. This causes the paste to become more or less diluted by uptake of moisture from the ambient air in the time between its application and its removal from the surface to be etched. The etching power of the paste is constantly weakened with increasing etching duration. At the same time, the viscosity of the paste decreases due to the liquid taken up, and the printed-on pastes in the form of lines or structures deliquesce. With increasing exposure time, printed-on lines broaden due to this effect. The liquefying and deliquescing pastes round the sides of the etched trenches and start to etch surfaces which were previously intact. At the same time, the maximum achievable etching depth is limited by the constant dilution. In addition, only pure silicon surfaces can be structured with sufficient speed in an industrial process using the known pastes comprising potassium hydroxide. By contrast, it has hitherto been necessary for multilayered systems consisting of pure silicon layers and layers of silicon derivatives, for example of phosphosilicate glass, to be etched successively with different paste types in successive steps.
[1] W. Wettling, Phys. Bl. 12 (1997), pp. 1197-1202
[2] J. Horzel, J. Slufzik, J. Nijs, R. Mertens, Proc. 26th IEEE PVSC, (1997), pp. 139-42
[3] M. Schnell, R. Lüdemann, S. Schäfer, Proc. 16^{th} EU PVSEC, (2000), pp. 1482-85
[4] D. S. Ruby, P. Yang, S. Zaidi, S. Brueck, M. Roy, S. Narayanan, Proc. 2^{nd} World Conference and Exhibition on PVSEC, (1998), pp. 1460-63
[5] U.S. Pat. No. 6,091,021 (2000), D. S. Ruby, W. K. Schubert, J. M. Gee, S. H. Zaidi
[6] U.S. Pat. No. 5,871,591 (1999), D. S. Ruby, J. M. Gee, W. K. Schubert
[7] EP 0229915 (1986), M. Bock, K. Heymann, H.-J. Middeke, D. Tenbrink
[8] WO 00/40518 (1998), M. Luly, R. Singh, C. Redmon, J. Mckown, R. Pratt
[9] DE 10101926 (2000), S. Klein, L. Heider, C. Zielinski, A. Kübelbeck, W. Stockum
[10] A. F. Bogenschütz, Ätzpraxis für Halbleiter [Etching Practice for Semiconductors], Carl Hanser Verlag, Munich 1967
[11] WO 2004/032218 A1.

Object

The object of the present invention is therefore to provide a corresponding simple and inexpensive process and an etching paste which can be employed therein, enabling the disadvantages and problems outlined above to be avoided and by means of which silicon surfaces can be etched selectively for the production of emitters and in order to improve the antireflection behaviour.

### DESCRIPTION OF THE INVENTION

The object is achieved, in particular, by the provision of an etching medium for etching silicon surfaces and layers in the form of a thickened, paste-form, alkaline composition which, besdies suitable thickeners, comprises extremely fine, low-melting polymer particles.

Particle-containing, alkaline compositions of this type can be prepared inexpensively. They can be applied rapidly and selectively to the areas to be etched, for example using a screen printer or a dispenser. The desired etching process is carried out, preferably at elevated temperatures, after the paste has been printed on in the form of extremely fine lines and structures. Surprisingly, the particles present have a stabilising action here on the shapes of the printed-on lines and structures of the etching pastes.

Besides the described opening of the p-n junctions of a solar cell, selective (also two-stage) emitters are produced in mass production by selective etching of silicon using the etching pastes according to the invention. At the same time, the use of the novel etching pastes facilitates an improvement in the antireflection behaviour of the solar cell, enabling undercutting of the silicon layers at ridges, edges and in etched trenches to be inhibited or prevented.

The present invention thus relates to a printable and dispensable alkaline etching medium in the form of a particle-containing etching paste which comprises
a. at least one solvent,
b. optionally thickening agents,
c. extremely fine organic particles having a low melting point and optionally extremely fine inorganic particles,
d. optionally additives, such as antifoams, thixotropic agents, flow-control agents, deaerators, adhesion promoters.

This etching medium is effective in the process according to the invention at temperatures higher than 70° C., it can preferably be employed at temperatures above 150° C., but lower than 200° C., with low-melting particles present melting.

Etching media according to the invention comprise, as etching component, an organic or inorganic base, preferably at least one component selected from the group sodium hydroxide, potassium hydroxide, ammonia, ethanolamine, ethylenediamine, tetraalkylammonium hydroxide or a mixture of these bases. It is also possible to employ mixtures, such as, for example, ethylenediamine/pyrocatechol, ethanolamine/gallic acid. However, bases from the first-mentioned group are preferentially used for this purpose. Sodium hydroxide and/or potassium hydroxide are particularly preferentially used as etching components in the compositions. Accordingly, etching media according to the invention preferably comprise NaOH and/or KOH as etching component in a concentration of 2 to 50% by weight, preferably 5 to 48% by weight, based on the total amount.

An essential constituent of the pastes according to the invention which advantageously influences the etching result are finely particulate powders. These may be both inorganic and organic powders. They are preferably organic polymer powders having a low melting point. Polyolefin powders have proven particularly suitable, especially polyethylene, polypropylene or corresponding copolymer powders. In particular, polymer powders having a melting point below 150° C. give particularly good results on use of the pastes. For the preparation of the pastes, corresponding polymer powders can be added in an amount of 1 to 50% by weight, preferably in an amount in the range from 10 to 50% by weight, based on the total amount of the composition. Experiments have shown that both the printing-on of the pastes in the form of very thin lines or extremely fine structures is possible with a good result if the particles of the polymer powders used have relative particle diameters in the range from 10 nm to 30 μm. Particularly good print results are achieved on use of powders having relative particle diameters of 1 to 10 μm and if the viscosity of the paste is in a suitable range. The pastes can be printed very well if they have a viscosity in the range from 20 to 40 Pas. Preference is given to the use of etching pastes which have a viscosity in the range from 25 to 35 Pas.

Furthermore, a part of the organic polymer powders may be replaced by inorganic finely particulate powders. Inorganic powders which can be added are preferably extremely fine graphite or extremely fine carbon-black powder.

Solvents which may be present in the etching media according to the invention are those selected from the group water, isopropanol, diethylene glycol, dipropylene glycol, polyethylene glycols, 1,2-propanediol, 1,4-butanediol, 1,3-butanediol, glycerol, 1,5-pentanediol, 2-ethyl-1-hexanol or mixtures thereof, or solvents selected from the group acetophenone, methyl-2-hexanone, 2-octanone, 4-hydroxy-4-methyl-2-pentanone, 1-methyl-2-pyrrolidone, ethylene glycol monobutyl ether, ethylene glycol monomethyl ether, triethylene glycol monomethyl ether, diethylene glycol monobutyl ether, dipropylene glycol monomethyl ether, carboxylic acid esters, such as [2,2-butoxy(ethoxy)]ethyl acetate, propylene carbonate, in pure form or in the form of a mixture or mixtures which comprise both solvents from the first group and also from the second group. The etching media according to the invention usually comprise solvents in an amount of 10 to 90% by weight, preferably in an amount of 15 to 85% by weight, based on the total amount of the medium.

The etching media according to the invention furthermore comprise a thickener selected from the group consisting of hydroxyalkylguar, xanthan gum, cellulose and/or ethyl-, hydroxypropyl- or hydroxy-ethylcellulose, carboxymethylcellulose, sodium carboxymethyl-hydroxyethylcellulose, homopolymers or copolymers based on functionalised vinyl units of acrylic acid, acrylates and alkyl methacrylates (C₁₀-C₃₀), individually or in a mixture in an amount of from 0.5 to 25% by weight, preferably from 1 to 10% by weight, based on the total amount of the etching medium.

Besides these components, additives selected from the group consisting of antifoams, thixotropic agents, flow-control agents, deaerators and adhesion promoters may be present in an amount of from 0 to 2% by weight, based on the total amount.

Additives having advantageous properties for the desired purpose are, for example, commercially available

antifoams, such as, for example, TEGO® Foamex N,

thixotropic agents, such as BYK® 410, Borchigel® Thixo2,

flow-control agents, such as TEGO® Glide ZG 400,

deaerators, such as TEGO® Airex 985 or

adhesion promoters, such as Bayowet® FT 929.

Further additives are mentioned in the following detailed description of the invention. It goes without saying to the person skilled in the art that these additives may also be replaced by other commercially available products with the same action. The essential factor in this connection is that the addition of such additives improves the product properties.

Additives specifically employed in experiments carried out are also indicated in the examples given below. These may have a positive influence on the printability of the etching paste.

Besides the novel etching paste, the present invention also relates to a process for the selective etching of silicon surfaces and layers in which the etching medium is applied over the entire area or selectively in accordance with an etching structure mask specifically only to the areas of the surface at which etching is desired. After the selected exposure time of 30 s to 5 min at a temperature above the melting point of the powder particles present in the etching paste, the etching medium is removed again.

In accordance with the invention, the etching medium acts at a temperature in the range from higher than 70° C. to about 150° C., preferably higher, but at temperatures lower than 200° C. The action temperature is preferably set to a temperature higher than the melting point of the polymer particles added, preferably higher than 150° C., but as far as possible not higher than 200° C. The activation and setting of the temperature are preferably carried out by input of energy, particularly preferably by IR radiation.

In the process according to the invention, the etching medium is applied to the surface to be etched by a screen, template, pad, stamp, ink-jet or manual printing process or in a dispensing technique. After the exposure time and after etching, the etching medium is rinsed off with water or another solvent or with a solvent mixture.

The etching media according to the invention can be used in production processes in photovoltaics, semiconductor technology, high-performance electronics or display manufacture, in particular for the production of photodiodes, circuits, electronic components or for etching silicon surfaces and layers for opening the p-n junction in solar cells. They can also be used for etching silicon surfaces and layers for the production of a selective emitter for solar cells, for etching silicon surfaces and layers of solar cells for improving the antireflection behaviour, for etching silicon surfaces and layers in a process for the production of semiconductor components and circuits thereof, or for etching silicon surfaces and layers in a process for the production of components in high-performance electronics.

### OBJECT OF THE INVENTION

The object of the invention is for semiconductor surfaces and layers, in particular silicon surfaces and layers, to be etched or structured over the entire area or selectively using etching pastes. A technique with a high degree of automation and high throughput which is suitable for transfer of the etching paste to the area to be etched is printing and dispensing. In particular, screen, template, pad, stamp and ink-jet printing processes and the dispensing process are known to the person skilled in the art. Manual application, for example by means of a brush and/or application roller, is likewise possible.

Depending on the screen, template, klischee or stamp design or cartridge or metering unit control, it is possible to apply the etching pastes described in accordance with the invention over the entire area or selectively in accordance with the etching structure mask only to the areas where etching is desired. All masking and lithography steps are superfluous in this case.

It is thus possible for structuring processes with complex masking or processes such as laser structuring to be significantly shortened and carried out less expensively or for processes which are susceptible to technological faults, such as plasma etching, to be replaced by printing and dispensing techniques. In addition, the etching process can be significantly reduced with respect to the consumption of etching chemicals since the etching paste is only applied to the areas to be etched.

In particular during parting of the p-n junction in the production of silicon solar cells, the following advantages can be achieved through the use of the etching pastes according to the invention:
no need for expensive plasma-etching units
reduction in the high cell breakage rates that occur
minimisation of the high loss of material during mechanical cutting
avoidance of surface defects

In the production of the selective emitter using etching pastes, it is likewise possible to dispense with oxide masking and expensive plasma etching. In addition, selective application of the etching paste avoids underetching of the contact areas. Since masking is not required, even by screen-printed metal contact lines, etching damage to the contacts is excluded.

It should also be noted that, in contrast to the photolithographic, plasma-chemical and laser processes used hitherto, the production of a selective emitter and the improvement in the antireflection behaviour can be made significantly shorter and simpler with the etching paste according to the invention. The wafers can be uniformly n⁺⁺-doped over the entire area. The areas between the contacts are etched away by the etching paste, thus n⁺-doped and improved in their antireflection behaviour. A plurality of process steps are thus saved.

The etching operation is preferably carried out with the input of energy, for example in the form of heat radiation (IR lamp) or by means of a hotplate. When etching is complete, the etching pastes are rinsed off the etched surface using a suitable solvent or solvent mixture.

The etching duration can be between a few seconds and several minutes depending on the application, desired etching depth and/or edge sharpness of the etch structures and the etching temperature set.

The etching pastes according to the invention have the following composition:
etching alkaline components
solvents
thickeners
finely divided, low-melting organic powders and optionally finely divided inorganic powders
if desired additives, such as, for example, antifoams, thixotropic agents, flow-control agents, deaerators and adhesion promoters

In order to etch semiconductor elements from main group 4 of the Periodic Table, such as silicon, strong caustic lyes are used in accordance with the invention [7]. The etching action of the etching pastes described in accordance with the invention is therefore based on the use of alkaline, silicon-etching solutions.

The alkaline etching components used in the etching pastes described in accordance with the invention can be aqueous solutions of inorganic lyes, such as sodium hydroxide, potassium hydroxide, ammonia or organic-based, alkaline etching mixtures, such as ethylenediamine/pyrocatechol, ethanolamine/gallic acid, tetraalkylammonium hydroxide or combinations of the two. Particular preference is given to compositions which comprise only sodium hydroxide and/or potassium hydroxide. Very particular preference is given to compositions which comprise sodium hydroxide as etching component. Particularly good etching results are also obtained if sodium hydroxide and potassium hydroxide are employed together in a suitable mixing ratio. This mixing ratio is advantageously approximately at a KOH:NaOH ratio of 2:1. This ratio may also be shifted somewhat upward or downward.

The proportion of etching components employed is in a concentration range of 2-50% by weight, preferably 5-48% by weight, based on the total weight of the etching paste. Particular preference is given to etching media in which the etching components are present in an amount of 10-45% by weight. Particularly suitable are etching media in which the etching component(s) is (are) present in an amount of 30-40% by weight, based on the total weight of the etching paste, since etching rates which facilitate complete opening of the p-n junction have been found for etching media of this type and semiconductor elements can be treated with high throughput. At the same time, these etching pastes show high selectivity for the surface layers to be etched.

The etching components are already effective in the etching pastes at 70-150° C. However, experiments have shown that improved etching results are achieved if the temperature is raised rapidly during the etching operation to just above the melting point of the polymer particles present, so that the etching is preferably carried out at temperatures above 150° C. The etching with the etching media according to the invention is therefore preferably carried out at temperatures below 200° C.

As already stated above, both inorganic and organic powders, preferably organic polymer powders, may have been added to the etching pastes. These powders can be extremely finely particulate powders comprising polymers selected from the group polystyrene, polyacrylate, polyamide, polyimide, polymethacrylate, melamine resin, urethane resin, benzoguanine resin, phenolic resin, silicone resin, fluorinated polymers (PTFE, PVDF, inter alia), or polyolefines, such as polyethylene or polypropylene, and micronised wax, which, in the molten state, are not miscible with the other components of the etching paste, but instead form a two-phase system. Suitable inorganic powder additions are, in particular, those which are inert in the presence of strong bases, which are employed as etching components. Extremely fine graphite or carbon-black powders can therefore preferably be employed for this purpose.

Polyolefin powders have proven particularly suitable for this use, in particular polyethylene, polypropylene or corresponding copolymer powders. Various extremely finely particulate polyethylene powders may be suitable for this purpose. Both LD-PE powders and also HD-PE powders can be employed in the pastes. The essential factors in this connection are the melting point of the polymers and the fact that a two-phase system forms from the paste composition on rapid melting.

In particular, polymer powders having a melting point below 150° C. give particularly good results on use in the pastes. For the preparation of the pastes, corresponding polymer powders can be added in an amount, based on the total amount of the composition, of 1 to 50% by weight, preferably in an amount in the range from 10 to 50% by weight.

Experiments have shown that both the printing-on of the pastes in the form of very thin lines or extremely fine structures is possible with a good result if the particles of the polymer powders used have relative particle diameters in the range from 10 nm to 30 μm. Particularly good printing results are achieved on use of powders having relative particle diameters of 1 to 10 μm and if the viscosity of the paste is in a suitable range.

It has furthermore been found that a total amount of particles of 50% by weight, based on the composition as a whole, should not be exceeded in compositions in which both organic polymer particles and also inorganic particles are present. At the same time, the content of fusible particles should be sufficiently high that, on heating above the melting point of the polymer particles, a continuous polymer layer forms on the printed-on paste on the surface that terminates the paste to the outside. In the most favourable case, this is achieved if at least 1% by weight of organic polymer particles, based on the composition as a whole, are present in the paste composition. Advantageous conditions exist if the content of organic polymer particles is higher. Preference is therefore given to the use of paste compositions in which the content of organic polymer particles is at least 2% by weight, based on the composition as a whole, even if inorganic particles are also present in the paste.

The following inorganic or organic solvents, which can be used in pure form or as a mixture, are suitable for the preparation of the etching pastes according to the invention:
water
simple or polyhydric alcohols (for example isopropanol, diethylene glycol, dipropylene glycol, polyethylene glycols, 1,2-propanediol, 1,4-butanediol, 1,3-butanediol, glycerol, 1,5-pentanediol, 2-ethyl-1-hexanol) or mixtures thereof
ketones (for example acetophenone, methyl-2-hexanone, 2-octanone, 4-hydroxy-4-methyl-2-pentanone, 1-methyl-2-pyrrolidone)
ethers (for example ethylene glycol monobutyl ether, ethylene glycol monomethyl ether, triethylene glycol monomethyl ether, diethylene glycol monobutyl ether, dipropylene glycol monomethyl ether)
carboxylic acid esters (for example [2,2-butoxy(ethoxy)]ethyl acetate)
esters of carbonic acid (for example propylene carbonate)

Thus, water and the said alcohols can be employed in pure form or as a mixture. However, ketones, ethers, carboxylic acid esters and esters of carbonic acid in pure form or as a mixture can also be employed as solvent solvent. Under certain conditions, it may also be appropriate to employ other mixtures of solvents selected from the various groups.

Preference is given to the use of water and solvents from the group consisting of the ethers and ketones.

Water has proven particularly suitable.

The proportion of the solvents in the composition as a whole can be in the range from 10-90% by weight, preferably 15-85% by weight, based on the total weight of the etching paste. Particularly suitable compositions have proven to be those in which solvents are present in an amount of 55-75% by weight, based on the total weight of the etching paste.

The viscosity of the etching pastes described in accordance with the invention is set by means of network-forming thickeners which swell in the liquid phase and can be varied depending on the desired area of application. Particularly good etching results are achieved if the viscosity of the etching paste prepared is in a range from 20 to 40 Pas. Preference is given to the use of etching pastes which have a viscosity in the range from 25 to 35 Pas.

The viscosity can be determined using a Brookfield rotational viscometer. For this purpose, the viscosity curves are measured at room temperature (25° C.) using a spindle (No. 7) at 5 revolutions per minute and the viscosity is measured under otherwise identical conditions at different rotational speeds up to 50 revolutions per minute. The viscosity can be determined more accurately using a cone-and-plate rheometer, for example an instrument from Haake (Haake RotoVisco 1) or Thermo Electron Corporation.

For the measurement, the sample is located in a shear gap between a very flat cone and a coaxial plate. A uniform shear rate distribution is formed in the measurement gap through the choice of the cone angle. Control takes place via the number of revolutions (CSR) or the torque (CSS). Correspondingly, the number of revolutions or torque respectively is measured. The direct stresses can be derived via force transducers on the drive shaft or on the underside of the cone. In the present case, the measurement system used was a CP 2/35 system, where the cone has a diameter of 35 mm and an angle of 2° . For the measurement, a 2.5 g sample is employed in each case. The viscosity curve is measured automatically under microprocessor control at a temperature of 23° C. with a shear rate in the range 10-75 s⁻¹. The average measurement value is obtained from 20 measurements. The standard value determined is a value at a shear rate of 25 s⁻¹. Corresponding measurement methods are described in greater detail in the standards DIN 53018 and ISO 3210.

If desired, the viscosity can be adjusted by addition of solvent, in the simplest case by addition of water, and/or other liquid components and/or other viscosity assistants.

The pastes according to the invention should have a viscosity in a range from 20 to 40 Pas in order, for example during screen printing, to ensure a uniform flow through the screen during printing. Since the pastes according to the invention have thixotropic properties, the viscosity drops under the action of shear forces, meaning that the viscosity varies in a certain range for a specific composition.

In particular, the addition of inorganic graphite or carbon-black powder having relative particle diameters of less than 80 nm, in particular less than 50 nm, preferably from 45 nm to 30 nm, and a specific BET surface area in the range from 40 to 100 m²/g, preferably from 50 to 70 m²/g, gives improved results. Very particular preference is given to the use of carbon-black powders having particle diameters of about 40 nm and a specific BET surface area of about 62 m²/g. Thus, the use of powders of this type having a relative particle diameter of about 40 nm and a specific BET surface area of about 62 m²/g results in compositions having improved environmental properties; more precisely, it has been found that the total powder addition can be considerably reduced for the preparation of a paste having a viscosity of less than 40 Pas, in particular about 30 Pas.

The pastes according to the invention can be prepared using commercially available graphite or carbon-black powders which have the properties described above and meet the size and surface requirements. Mention may be made here by way of example of the commercial product Super P™ (conductive carbon black from TIMCAL Graphite & Carbon, Switzerland).

The use of carbon-black particles also enables the service life of the waste-water filters necessary for the removal of suspended particles from the waste water to be considerably extended, more precisely for the removal of the suspended particles from the waste water produced in the rinsing operations for cleaning the etched surfaces.

Surprisingly, measurements have shown that the rinsed-off carbon-black particles (active carbon) have an adsorptive action for the organic thickener additives and organic solvent components of the paste. This has the consequence that the BODS value (mg/l) in the rinse water can be reduced by simple particle filtration. The BOD5 value is the biological oxygen demand (mg/l) of waste water in 5 days, measured in accordance with DIN 38409 H51.

The particle sizes, of both the inorganic and organic polymer particles, can generally be determined using conventional methods. For example, the particle size can be determined by means of particle correlation spectroscopy (PCS), with the investigation being carried out using a Malvern Zetasizer in accordance with the instruction manual. The diameter of the particles is determined here as the d₅₀ or d₉₀ value. The particle diameters indicated are preferably quoted as d₅₀ values.

The particle diameters can generally be determined by means of laser diffraction combined with on-line analysis. To this end, a laser beam is shone into a particle cloud distributed in a transparent gas, for example air. The particles refract the light, with small particles refracting the light at a greater angle than large particles. The scatter angle is thus directly correlated to the particle size. The observed scatter angle increases logarithmically with decreasing particle size. The refracted light is measured by a number of photodetectors arranged at various angles. The measurements are preferably evaluated using Mie light diffraction theory, which is based on Maxwell's electromagnetic field equation. This theory is based on two assumptions. Firstly, it is assumed that the particles to be measured are spherical, but this only really applies to few particles. The measured laser diffraction is used to calculate the volume of particles. Secondly, dilute particle suspensions are assumed. The method usually used to determine particle sizes in the nano range by dynamic light scattering is described in greater detail in the brochure “Dynamic Light Scattering: An Introduction in 30 Minutes”, DLS technical note, MRK656-01 from Malvern Instruments Ltd.

The particle size in the nanoparticulate range can also be determined with the aid of scanning electron photomicrographs (SEM photographs). To this end, particle-containing emulsions can be prepared and applied to a suitable surface in an extremely thin layer in a spin-coating process. After evaporation of the solvent, SEM photographs are taken and the particle diameters recorded are measured. The relative particle diameter of the measured sample is determined by statistical evaluation. Standardised methods for determining particle sizes and devices suitable for this purpose are described in ISO 13321, Methods for Determination of Particle Size Distribution Part 8: Photon Correlation Spectroscopy, International Organisation for Standardisation [(ISO) 1996 (First Edition Jul. 1, 1996)], including methods for determining sizes in the nm measurement range.

Possible thickening agents which are added in order to adjust the viscosity are crosslinked or uncrosslinked homopolymers and copolymers based on monomer units such as functionalised vinyl units, for example acrylic acid, acrylates, alkyl methacrylates (C₁₀-C₃₀) and hydroxyalkylguar. The thickeners may be employed individually and/or in combinations with other thickeners. Preference is given to the use of crosslinked acrylic acid polymers as thickening agents. The sodium salt of carboxymethylcellulose (Finnfix®) and in particular crosslinked acrylic acid homopolymers (Carbomers®) have proven very particularly suitable for this purpose.

The proportion of thickening agents necessary for the specific setting of the viscosity range and for the formation of a printable or dispensable paste is in the range 0.5-25% by weight, preferably 1-10% by weight, based on the total weight of the etching paste. Particularly suitable compositions have proven to be those in which thickeners are present in an amount of 1.5-6% by weight.

Additives having properties which are advantageous for the desired purpose are antifoams, for example TEGO® Foamex N (dimethylpoly-siloxane), thixotropic agents, for example BYK® 410 (modified urea), Borchigel® Thixo2, flow-control agents, for example TEGO® Glide ZG 400 (polyether-siloxane copolymer), deaerators, for example TEGO® Airex 986 (polymer with silicone tip), and adhesion promoters, for example Bayowet® FT 929 (fluorosurfactant). These can positively influence the printability and dispensability of the etching paste. The proportion of the additives is in the range 0-2% by weight, based on the total weight of the etching paste.

It has furthermore been found through experiments that both the choice of the components employed for the preparation of the etching media and the mixing ratio of the components to one another in the etching media are of considerable importance. Depending on the manner in which the etching media are applied to the area to be etched, the percentage ratio of the components to one another should be set differently, since, inter alia, the viscosity and flowability or the thixotropy being set are considerably influenced by the amounts of solvent and thickener present. The amounts of solvent and thickener present in turn influence the etching behaviour. Depending on the type of use in the process according to the invention, it is therefore possible for the person skilled in the art to select a correspondingly adapted composition of the etching medium.

For the preparation of the etching pastes, the various components are mixed with one another successively with adequate mixing, more precisely in such a way that the temperature is only able to increase moderately during the addition of the etching component, but a paste having a suitable viscosity forms during the mixing.

The etching pastes according to the invention can be printed in a known manner onto the wafer surfaces or semiconductor surfaces and can even be printed in fine line printing <50 μm. This is possible, for example, through the use of a suitable screen.

Areas of Application

The etching pastes according to the invention can be used in:
the solar-cell industry
the semiconductor industry
high-performance electronics

The etching pastes according to the invention can be employed in all areas where full-area and/or structured etching of silicon surfaces or layers is desired. Thus, individual structures can be etched over the entire area or selectively to the depth desired in each case in a silicon surface or layer.

Areas of application are, for example:
all etching steps (synonymous with structuring steps), including surface cleaning/roughening of silicon surfaces and layers which result in the production of optoelectrical components, such as solar cells, photodiodes and the like, in particular parting of the p-n junction in silicon solar cells and the partial removal of doped layers (selective emitters)
all etching steps on silicon surfaces and layers which result in the production of semiconductor components and circuits
all etching steps on silicon surfaces and layers which result in the production of components in high-performance electronics (IGBTs, power thyristors, GTOs, etc.).

As already mentioned above, it has surprisingly been found that the use of the alkaline etching pastes according to the invention to which extremely fine, low-melting organic powders are added makes it possible to obtain significantly more precise lines or structures with considerably improved edge sharpness. At the same time, it has been found that the use of NaOH and KOH in a mixture as etching components makes it possible considerably to improve the average etching rates of oxidic surfaces, enabling the through-etching of silicon compounds, such as, for example, phosphosilicate glass, on an industrial scale. The improved properties and higher etching rates mean that the etching pastes according to the invention can now also be employed in the industrial high-throughput semiconductor element manufacturing process.

As already mentioned above, investigations of the etching pastes during and after the etching process with exposure to heat have surprisingly shown that the low-melting particulate additions present do not mix with the other components of the etching paste composition on melting, but instead form an organic phase which floats and settles on the surface of the printed-on etching paste like a thin layer. The polymer layer or polymer membrane formed in this way appears to have a considerable influence on the behaviour of the etching paste and the etching rate, since the compositions according to the invention are effective over a longer time with a higher etching rate than comparable, already known compositions which comprise particle-form additions, but do not change their physical state at temperatures above 150 and below 200° C. In addition, the polymer layer prevents thin printed-on etching paste lines from deliquescing during etching and thus resulting in broader structures.

The object according to the invention is thus achieved by adding extremely fine low-melting polymer particles to alkaline etching pastes. At temperatures just above the melting point, the molten polymers form a polymer membrane on the surface of the printed-on lines or structures of the etching medium which prevents both evaporation of solvent from the etching paste and also ingress of moisture. In this way, the etching action of the now encapsulated etching paste is retained. Surprisingly, it has now become possible using these etching paste compositions according to the invention to form etching structures which are narrow and deep, and also have a complex shape very precisely in surfaces of solar-cell silicon.

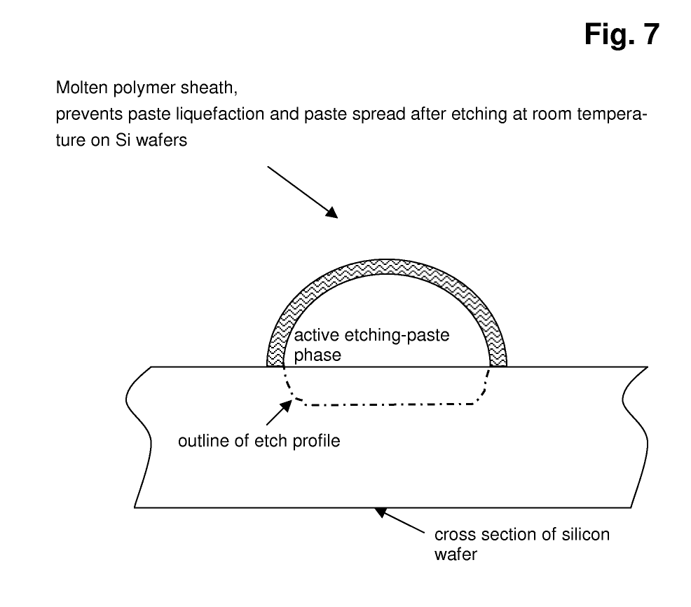

FIG. 7 shows a diagrammatic representation of the behaviour of the low-melting polymer particles during heating and during the etching process. While a polymer membrane has formed, the etching component can become selectively active under the underlying surface.

As has already been established above, heating of the wafer or semiconductor element printed with the etching pastes according to the invention to temperatures above the melting point of the polymer particles present does not result in an impairment of the etching result, but instead in a considerable improvement of the properties of the etched structures.

In order to carry out the etching process, for example, a wafer printed with etching paste is heated for 2 minutes on a hotplate at about 200° C. This temperature is preferably selected if the etching pastes used comprise polymer particles having a melting point of about 150° C. The heating to this temperature has, as already described above, the consequence that the polymer particles melt and a second phase forms of the paste on the paste surface, a so-called polymer membrane. This polymer membrane prevents evaporation of moisture during the etching process. The mobility of the etching component present is thus maintained for longer, enabling a better etching behaviour to be achieved. In general, the temperature to which heating is carried out during the exposure time is thus set in such a way that the polymer particles melt in an extremely short time and an organic layer forms on the surface of the etching paste as quickly as possible.

After the actual etching step, the etched substrate is returned to room temperature, with the polymer membrane on top of the etching paste solidifying and preventing absorption of moisture by the hygroscopic etching component. The printed-on etching paste thus also retains its shape in this phase, and lateral spread and rounding of the etched structure do not take place.

Whereas the diffusion-in of atmospheric moisture on use of known alkaline etching pastes can result in the etching medium migrating or running to the opposite side of the wafer in the case of structuring processes close to the edge, this effect can be completely suppressed on use of the compositions according to the invention.

The specific composition of the etching pastes according to the invention, which may comprise NaOH and/or KOH as etching components, mean that it has become possible to employ them in structuring processes immediately before immersion into an HF bath, since these compositions etch Si layers as well as PSG (phosphosilicate glass from the n-doping step). In this way, a washing step and a drying step can advantageously be saved.

Since the use of the etching pastes according to the invention in the solar cell manufacturing process enables improved etching profiles with better flank steepness to be achieved, it has also become possible to print and etch desired structures closer together. This means that space is gained on the surface of the solar cells.

The present description enables the person skilled in the art to apply the invention comprehensively. In the case of any lack of clarity, it goes without saying that the cited publications and patent literature should be employed. Accordingly, these documents are regarded as part of the disclosure content of the present description.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present application to these alone.

It goes without saying to the person skilled in the art that, both in the examples given and also in the remainder of the description, the component amounts present in the paste compositions always only add up to 100% by weight, based on the composition as a whole, and cannot go beyond this, even if higher values could arise from the percentage ranges indicated.

The temperatures given in the examples and description and in the claims are always quoted in ° C.

### EXAMPLES

### Example 1

31 g of KOH

14 g of NaOH

60 g of water

5 g of ethylene glycol monobutyl ether

3.5 g of Carbomer (thickener)

3 g of LD-PE powder (d50: <20 μm, melting point: 107° C.)

The chemicals were weighed into a beaker and mixed using a paddle stirrer (stirring time 2-4 hours) until a homogeneous, printable paste has formed. The paste is subsequently transferred into a PE container.

The transfer into containers is carried out after a short standing time.

The present composition gives an etching paste with which, for example, silicon surfaces and layers can be etched specifically over the entire area or in a structured manner down to a desired depth with input of energy. By means of energy input, a temperature higher than 107° C., preferably a temperature of about 115° C., is set.

The etching paste is applied to the silicon surface, for example by screen printing or using a dispenser (for example needle diameter of 260 μm), and etched on a hotplate for 3 minutes at about 115° C. On production of etching structures with a line width of about 1 mm on an n-doped (100) silicon wafer, the etching depth determined (depending on the printing and dispensing parameters) is 0.3-1 μm. The etching depth can be increased by increasing the KOH concentration and the line width. For line widths of 4 mm and KOH concentrations of 20-50% by weight, the etching depths are 2-3 μm.

The etching paste obtained is stable on storage, easy to handle and printable. It can be removed from the printed surface or layer or from the paste carrier (screen, doctor blade, template, stamp, klischee, cartridge, etc.) using a solvent, for example using water.

### Example 2

20 g of KOH

62 g of water

1.5 g of polyethylene glycol 200

3.5 g of Na salt of carboxymethylcellulose (Finnfix thickener)

3.0 g of HD-PE powder (d50: <25 μm, melting point: 134° C.)

The batch and processing are carried out as described in Example 1.

The etching paste is applied to the silicon surface using a dispenser (pin diameter 450 μm) and etched for 3 minutes at an etching temperature of 145° C. On production of etching structures with a line width of about 1 mm on an n-doped (100) silicon wafer, the etching depth determined (depending on the printing and dispensing parameters) is 0.2-1 μm.

### Example 3

45 g of KOH

60 g of water

8 g of ethylene glycol

3.2 g of Carbomer (thickener)

3.5 g of PP powder (d50: <35 μm, melting point: 165° C.)

The etching paste is prepared as described in Example 1.

The etching paste is applied to the silicon surface by screen printing or using a dispenser (pin diameter 450 μm) and etched for 3 minutes at an etching temperature of 180° C. The etching depth determined on production of etching structures with a line width of 1 mm is about 200 nm on a silicon wafer.

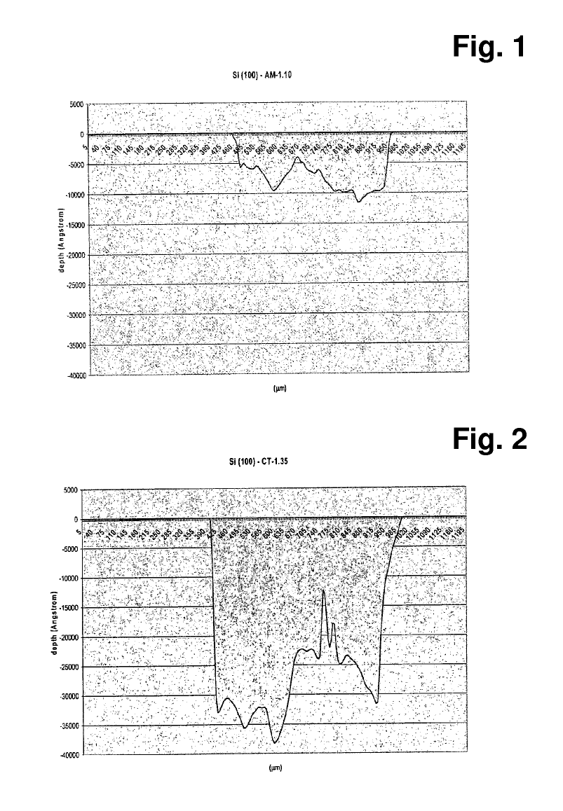

FIGS. 1 and 2 show the comparison of the etch depths which can be achieved under identical conditions in (100) silicon surface using the etching pastes according to the invention and using previously known etching pastes without addition of particles.

### Example 4

Description of the behaviour of the etching paste according to the invention

The pastes are applied to the silicon wafers as a frame (very close to the edge) by means of a dispenser. Each of the two wafers is subsequently placed on a hotplate at 200° C. for 2 min. during which the silicon is etched for edge insulation (parting of the p-n junction).

The following photographs show a silicon etching paste without addition of polymer compared with a silicon etching paste with addition of a low-melting polymer (melting point <160° C.). It can clearly be seen here that the paste without addition of polymer runs to a significantly greater extent (surface spread) on the textured silicon surface (the paste has no protective sheath against atmospheric moisture). By contrast, the paste with a polymer component exhibits no significant surface spread on the textured silicon wafer even 30 min after the etching step on the hotplate (2 min, 200° C.).

Strong surface spread is undesired in the mass production of solar cells!

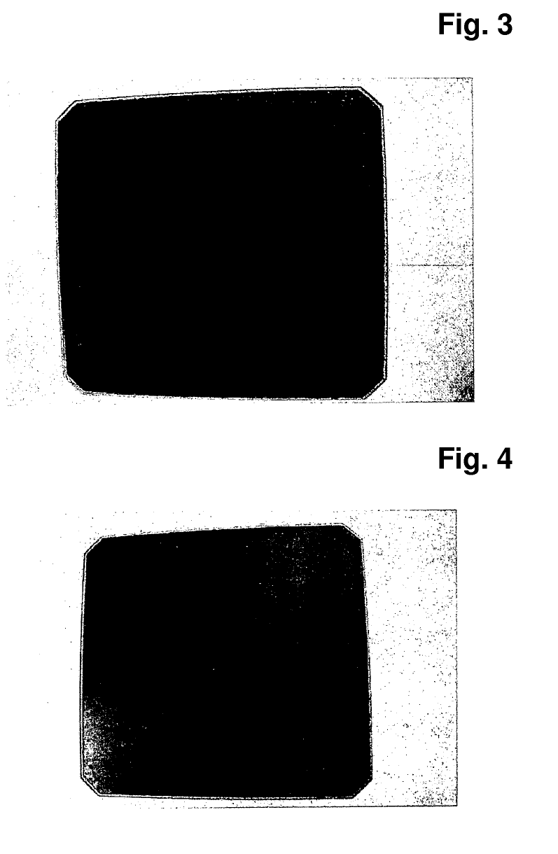

FIGS. 3 to 6 clearly show the improved behaviour of the etching pastes according to the invention with respect to precise etching compared with previously known etching pastes without addition of particles.

The figures shown below show the following:

FIG. 1 shows an etching profile produced using a particle-free etching paste in (100) silicon surface. The etching paste is a SolarEtch Si etching paste. At an etching duration of 2 min at 200° C., an etching depth of approximately 1.0 μm and an etched line width of approximately 500 μm are produced.

FIG. 2 shows an etching profile produced using an etching paste comprising low-melting polymer particles in (100) silicon surface. The etching paste is an etching paste according to the invention comprising low-melting polymer particles. At an etching duration of 2 min at 200° C., an etching depth of approximately 3.0 μm and an etched line width of 500 μm are produced.

FIG. 3 shows an Si wafer immediately after application of an etching paste without addition of polymer on etching on the hotplate at 200° C./2 min. A uniform print picture can be seen.

FIG. 4 shows an Si wafer immediately after application of an etching paste comprising low-melting polymer particles on etching on the hotplate at 200° C./2 min. A uniform print picture can be seen.

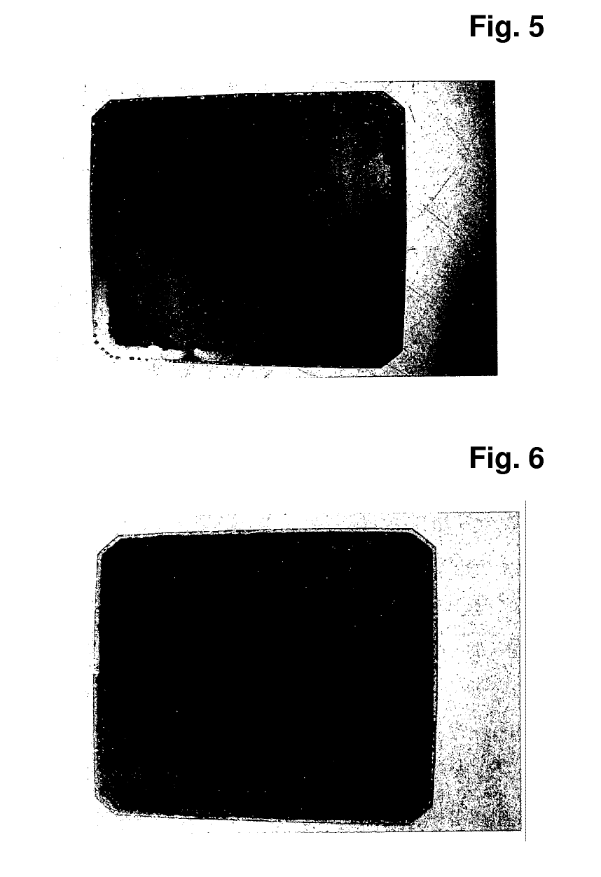

FIG. 5 shows the same Si wafer as in FIG. 3 above 30 min after etching using an etching paste without polymer on the hotplate at 200° C./2 min. The etch edges are frayed.

FIG. 6 shows the same Si wafer as in FIG. 4 above 30 min after etching using an etching paste comprising low-melting polymer particles on the hotplate at 200° C./2 min. The etch edges are uniform, meaning that a straight ridge is retained at the edge.

FIG. 7 shows a diagrammatic representation of the etching process with an alkaline etching paste comprising low-melting polymer particles at 200° C., with a cross-section of the etching paste on the silicon substrate being shown.

1. Printable, dispensable, alkaline etching medium for etching silicon surfaces and layers in the form of an etching paste comprising
a) at least one basic etching component,
b) at least one solvent,
c) extremely fine organic particles having a low melting point, and optionally inorganic particles,
d) optionally thickening agents, and
e) optionally additives, such as antifoams, thixotropic agents, flow-control agents, deaerators, adhesion promoters.

2. Etching medium according to claim 1, comprising extremely fine organic particles having a melting point >80° C. and <200° C.

3. Etching medium according to claim 1, characterised in that it comprises, as etching component, an organic or inorganic base in a concentration of 2 to 50% by weight, preferably 5 to 48% by weight, based on the total amount.

4. Etching medium according to claim 1 which is effective at temperatures higher than 70° C., preferably at temperatures above 150° C., with the particles melting.

5. Etching medium according to claim 1, comprising at least one etching component selected from the group sodium hydroxide, potassium hydroxide, ammonia, ethanolamine, ethylenediamine and tetraalkylammonium hydroxide or one of the mixtures ethylenediamine/pyrocatechol and ethanolamine/gallic acid.

6. Etching medium according to claim 1, comprising at least one etching component selected from the group sodium hydroxide and potassium hydroxide,

7. Etching medium according to claim 1, comprising extremely fine organic particles having a relative particle diameter in the range from 10 nm to 30 μm, preferably from 1 to 10 μm.

8. Etching medium according to claim 1, comprising at least one solvent selected from the group water, isopropanol, diethylene glycol, dipropylene glycol, polyethylene glycols, 1,2-propanediol, 1,4-butanediol, 1,3-butanediol, glycerol, 1,5-pentanediol, 2-ethyl-1-hexanol or mixtures thereof, or selected from the group acetophenone, methyl-2-hexanone, 2-octanone, 4-hydroxy-4-methyl-2-pentanone, 1-methyl-2-pyrrolidone, ethylene glycol monobutyl ether, ethylene glycol monomethyl ether, triethylene glycol monomethyl ether, diethylene glycol monobutyl ether, dipropylene glycol monomethyl ether, carboxylic acid esters, such as [2,2-butoxy(ethoxy)]ethyl acetate, propylene carbonate, as such or in a mixture in an amount of 10 to 90% by weight, preferably in an amount of 15 to 85% by weight, based on the total amount of the medium.

9. Etching medium according to claim 1, comprising a thickening agent selected from the group hydroxyalkylguar, xanthan gum, cellulose and/or ethyl-, hydroxypropyl- or hydroxyethylcellulose, carboxymethyl-cellulose, sodium carboxymethylhydroxyethylcellulose, homopolymers or copolymers based on functionalised vinyl units of acrylic acid, acrylates and alkyl methacrylates (C₁₀-C₃₀), individually or in a mixture in an amount of 0.5 to 25% by weight, preferably 1 to 10% by weight, based on the total amount of the etching medium.

10. Etching medium according to claim 1, comprising additives selected from the group antifoams, thixotropic agents, flow-control agents, deaerators and adhesion promoters in an amount of 0 to 2% by weight, based on the total amount of the composition.

11. Process for etching silicon surfaces and layers or glass-like surfaces and layers consisting of a silicon derivative, characterised in that an etching medium according to claim 1 is applied selectively to the surface and heated during the exposure time to a temperature at which the polymer powders present in the etching medium melt and form a thin polymer layer on the etching medium.

12. Process according to claim 11, characterised in that
a) said etching medium is applied over the entire area or in accordance with an etch structure mask specifically only to areas of the surface at which etching is desired, in the form of extremely fine lines or structures,
b) the etching medium acts on the surface during an exposure time of 30 s to 5 min at a temperature which is somewhat above the melting point of the polymer particles present in the etching paste, and
c) the etching medium is removed again using a solvent or solvent mixture or by the action of heat when the etching is complete.

13. Process according to claim 10, characterised in that the etching medium is optionally activated by input of energy and acts at a temperature higher than 80° C., preferably lower than 200° C.

14. Process according to claim 10, characterised in that the etching medium is activated by exposure to heat (IR lamp or hotplate).

15. Process according to claim 10, characterised in that the etching medium is applied to the surface to be etched by a screen, template, pad, stamp, ink-jet or manual printing process or by a dispensing technique.

16. Use of an etching medium according to claim 1 in photovoltaics, semiconductor technology, high-performance electronics, display manufacture and for the production of photodiodes, circuits and electronic components.

17. A method for etching silicon surfaces and layers for opening the p-n junction in solar cells comprising using a medium of claim 1.

18. A method for etching silicon surfaces and layers for the production of a selective emitter for solar cells comprising using a medium of claim 1.

19. A method for etching silicon surfaces and layers of solar cells for improving the antireflection behaviour comprising using a medium of claim 1.

20. A method for etching silicon surfaces and layers in a process for the production of semiconductor components and circuits thereof comprising using a medium of claim 1.

21. A method for etching silicon surfaces and layers in a process for the production of components in high-performance electronics comprising using a medium of claim 1.
